(19) United States
(12) Patent Application Publication
(10) Pub. No.: US 2019/0294044 A1
(43) Pub. Date: Sep. 26, 2019

(54) POSITIVE PHOTOSENSITIVE COMPOSITION, PATTERN USING SAME, AND METHOD OF MANUFACTURING PATTERN

(71) Applicant: ADEKA CORPORATION, Tokyo (JP)

(72) Inventors: Taiki MIHARA, Tokyo (JP); Junya MIYAKE, Tokyo (JP); Naomi SATO, Tokyo (JP)

(73) Assignee: ADEKA CORPORATION, Tokyo (JP)

(21) Appl. No.: 16/465,097

(22) PCT Filed: Nov. 29, 2017
(86) PCT No.: PCT/JP2017/042876

§ 371 Date: May 29, 2019

(30) Foreign Application Priority Data
Nov. 30, 2016 (JP) 2016-233519

(51) Int. Cl. G03F 7/039; G03F 7/004

(52) U.S. Cl. CPC G03F 7/0392; G03F 7/2004; G03F 7/0045

(57) ABSTRACT

Provided are: a positive photosensitive composition that exhibits excellent sensitivity at a time of being cured; a pattern using the same; and a method of producing a pattern. The positive photosensitive composition contains: a sulfonic acid derivative compound (A) represented by Formula (I) below, where X¹ represents a linear or branched alkyl group having 1 to 14 carbon atoms or the like; and R¹ represents a group represented by an aliphatic hydrocarbon group, an aryl group, an arylalkyl group, an acyl group-substituted aryl group, an alicyclic hydrocarbon group or the like, which aliphatic hydrocarbon group, aryl group or arylalkyl group has no substituent or is optionally substituted with a halogen atom or the like; and a polymer compound (B) required to contain a structural unit represented by Formula (III) below, where R⁵ represents a hydrogen atom or a methyl group; R⁶ represents an alkyl group having 1 to 4 carbon atoms or the like; f represents a number of 0 to 4; and symbols “*” mean that this group is bound with adjacent groups at the sites “*”:

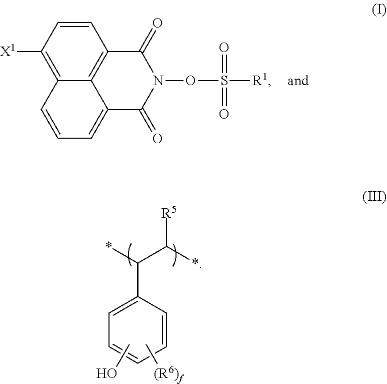

### TECHNICAL FIELD

The present invention relates to: a positive photosensitive composition (hereinafter, also simply referred to as “composition”); a pattern using the same; and a method of producing a pattern. More particularly, the present invention relates to: a positive photosensitive composition that exhibits excellent sensitivity at the time of being cured; a pattern using the same; and a method of producing a pattern.

### BACKGROUND ART

Sulfonyloxyimides having a naphthalimino group which is a radioactive functional group are substances that generate an acid when irradiated with an energy beam such as light, and they are used as, for example, photoacid generators contained in photolithography resist compositions used for the formation of an electronic circuit such as a semiconductor, and as cationic polymerization initiators contained in photopolymerizable compositions such as resin compositions for stereolithography, paints, coatings, adhesives, and inks.

Patent Documents 1 to 4 propose positive resists in which a hydroxystyrene-based resin and an acid generator, such as an onium salt or an oxium sulfonate compound, are used, and Patent Document 5 proposes a chemically amplified photoresist that contains a resin and a sulfonyloxyimide compound.

### RELATED ART DOCUMENTS

### Patent Documents

[Patent Document 1] JP2004-347852A

[Patent Document 2] JP2011-227416A

[Patent Document 3] JP4281326B2

[Patent Document 4] JP4682345B2

[Patent Document 5] JP2839172B2

### SUMMARY OF THE INVENTION

### Problems to be Solved by the Invention

However, in Patent Documents 1 to 5, the sensitivity during curing is not sufficiently examined, and there is thus room for further investigation.

In view of the above, an object of the present invention is to provide: a positive photosensitive composition that exhibits excellent sensitivity at the time of being cured; a pattern using the same; and a method of producing a pattern.

### Means for Solving the Problems

The present inventors intensively studied to solve the above-described problem and consequently discovered that the problem can be solved by using a sulfonic acid derivative compound having a specific structure and a specific polymer compound, thereby completing the present invention.

That is, the positive photosensitive composition of the present invention is characterized by containing:

a sulfonic acid derivative compound (A) represented by the following Formula (I):

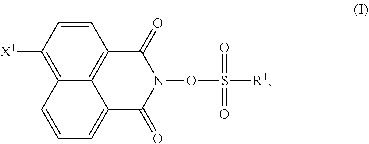

where X¹ represents a linear or branched alkyl group having 1 to 14 carbon atoms; a methylene group in the alkyl group is optionally substituted with —S—, —O—, —SO— or —SO₂—; R¹ represents an aliphatic hydrocarbon group having 1 to 18 carbon atoms, an aryl group having 6 to 20 carbon atoms, an arylalkyl group having 7 to 20 carbon atoms, an acyl group-substituted aryl group having 7 to 20 carbon atoms, an alicyclic hydrocarbon group having 3 to 12 carbon atoms, a 10-camphoryl group, or a group represented by the following Formula (II):

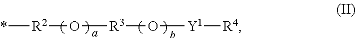

where Y¹ represents a single bond or an alkanediyl group having 1 to 4 carbon atoms; R² and R³ each independently represent an alkanediyl group having 2 to 6 carbon atoms, a halogenated alkanediyl group having 1 to 6 carbon atoms, an arylene group having 6 to 20 carbon atoms, or a halogenated arylene group having 6 to 20 carbon atoms; R⁴ represents a linear or branched alkyl group having 1 to 18 carbon atoms, a linear or branched halogenated alkyl group having 1 to 18 carbon atoms, an alicyclic hydrocarbon group having 3 to 12 carbon atoms, an aryl group having 6 to 20 carbon atoms, a halogenated aryl group having 6 to 20 carbon atoms, an arylalkyl group having 7 to 20 carbon atoms, or a halogenated arylalkyl group having 7 to 20 carbon atoms; a and b each represent 0 or 1; either a or b is 1; and a symbol “*” means that this group is bound with an adjacent group at the site “*”; and

the aliphatic hydrocarbon group having 1 to 18 carbon atoms, the aryl group having 6 to 20 carbon atoms, the arylalkyl group having 7 to 20 carbon atoms or the alicyclic hydrocarbon group having 3 to 12 carbon atoms has no substituent, or is optionally substituted with a halogen atom or a group selected from a halogenated alkyl group having 1 to 4 carbon atoms, an alkoxy group having 1 to 18 carbon atoms and an alkylthio group having 1 to 18 carbon atoms; and

a polymer compound (B) required to contain a structural unit represented by the following Formula (III):

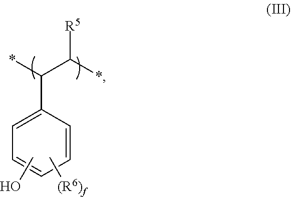

where R⁵ represents a hydrogen atom or a methyl group; R⁶ represents an alkyl group having 1 to 4 carbon atoms, an alkoxy group having 1 to 4 carbon atoms, or an alkoxycarbonyl group having 2 to 4 carbon atoms; f represents a number of 0 to 4; and symbols “*” mean that this group is bound with adjacent groups at the sites “*”.

In the composition of the present invention, X¹ is preferably an alkyl group having 4 carbon atoms. Further, in the composition of the present invention, R¹ is preferably a perfluoroalkyl group having 1 to 8 carbon atoms. Still further, in the composition of the present invention, the ratio of the structural unit represented by Formula (III) in the polymer compound (B) is preferably 50 to 90% by mole.

A pattern of the present invention is characterized in that it is obtained using the positive photosensitive composition of the present invention.

A method of producing a pattern of the present invention is characterized by including forming a pattern by irradiating the positive photosensitive composition of the present invention with heat or light.

### Effects of the Invention

According to the present invention, a positive photosensitive composition that exhibits excellent sensitivity at the time of being cured, a pattern using the same, and a method of producing a pattern can be provided.

### MODE FOR CARRYING OUT THE INVENTION

The present invention will now be described in detail based on embodiments thereof.

The positive photosensitive composition of the present invention contains a sulfonic acid derivative compound (A) represented by the following Formula (I):

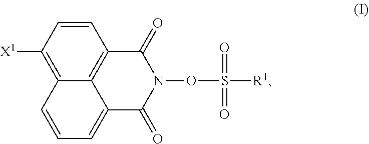

and a polymer compound (B) containing, as an essential, a structural unit represented by the following Formula (III):

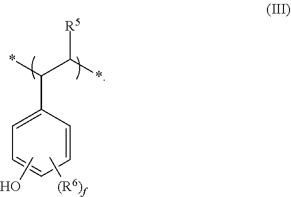

This composition exhibits excellent sensitivity at the time of being cured, and a cured product thereof has excellent heat resistance as well.

In Formula (I), X¹ represents a linear or branched alkyl group having 1 to 14 carbon atoms; a methylene group in the alkyl group is optionally substituted with —S—, —O—, —SO— or —SO₂—; R¹ represents an aliphatic hydrocarbon group having 1 to 18 carbon atoms, an aryl group having 6 to 20 carbon atoms, an arylalkyl group having 7 to 20 carbon atoms, an acyl group-substituted aryl group having 7 to 20 carbon atoms, an alicyclic hydrocarbon group having 3 to 12 carbon atoms, a 10-camphoryl group, or a group represented by the following Formula (II):

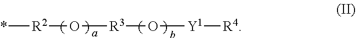

The aliphatic hydrocarbon group, the aryl group, the arylalkyl group or the alicyclic hydrocarbon group has no substituent, or a hydrogen atom thereof is optionally substituted with a halogen atom or a group selected from a halogenated alkyl group having 1 to 4 carbon atoms, an alkoxy group having 1 to 18 carbon atoms and an alkylthio group having 1 to 18 carbon atoms.

In Formula (II), Y¹ represents a single bond or an alkanediyl group having 1 to 4 carbon atoms; R² and R³ each independently represent an alkanediyl group having 2 to 6 carbon atoms, a halogenated alkanediyl group having 1 to 6 carbon atoms, an arylene group having 6 to 20 carbon atoms, or a halogenated arylene group having 6 to 20 carbon atoms; R⁴ represents a linear or branched alkyl group having 1 to 18 carbon atoms, a linear or branched halogenated alkyl group having 1 to 18 carbon atoms, an alicyclic hydrocarbon group having 3 to 12 carbon atoms, an aryl group having 6 to 20 carbon atoms, a halogenated aryl group having 6 to 20 carbon atoms, an arylalkyl group having 7 to 20 carbon atoms, or a halogenated arylalkyl group having 7 to 20 carbon atoms; a and b each represent 0 or 1; either a or b is 1; and a symbol “*” means that this group is bound with an adjacent group at the site “*”.

In Formula (III), R⁵ represents a hydrogen atom or a methyl group; R⁶ represents an alkyl group having 1 to 4 carbon atoms, an alkoxy group having 1 to 4 carbon atoms, or an alkoxycarbonyl group having 2 to 4 carbon atoms; f represents a number of 0 to 4; and symbols “*” mean that this group is bound with adjacent groups at the sites “*”.

### <Sulfonic Acid Derivative Compound (A)>

In Formula (I), X¹ represents a linear or branched alkyl group having 1 to 14 carbon atoms. Examples thereof include methyl, ethyl, propyl, isopropyl, 1-butyl, 2-butyl, isobutyl, tert-butyl, 1-pentyl, isopentyl, tert-pentyl, neopentyl, 1-hexyl, 2-hexyl, 3-hexyl, heptyl, 2-heptyl, 3-heptyl, isoheptyl, tert-heptyl, 1-octyl, isooctyl, tert-octyl, 2-ethylhexyl, 1-nonyl, isononyl, 1-decyl, 1-dodecyl, tridecyl, and tetradecyl. In these alkyl groups, methylene groups are optionally substituted with —S—, —O—, —SO— or —SO₂—. Thereamong, an alkyl group having 3 to 8 carbon atoms is preferred and an alkyl group having 4 carbon atoms is more preferred since these alkyl groups have both good solubility and good acid generation rate. A 1-butyl group is still more preferred since the material thereof is inexpensive and has good yield and low production cost. Further, the alkyl group is preferably an unsubstituted alkyl group.

In Formula (I), R¹ represents an aliphatic hydrocarbon group having 1 to 18 carbon atoms, an aryl group having 6 to 20 carbon atoms, an arylalkyl group having 7 to 20 carbon atoms, an acyl group-substituted aryl group having 7 to 20 carbon atoms, an alicyclic hydrocarbon group having 3 to 12 carbon atoms, a 10-camphoryl group, or a group represented by the above-described Formula (II). Among these groups, the aliphatic hydrocarbon group, the aryl group, the arylalkyl group and the alicyclic hydrocarbon group optionally do not have any substituent, or are optionally substituted with a halogen atom or a group selected from a halogenated alkyl group having 1 to 4 carbon atoms, an alkoxy group having 1 to 18 carbon atoms and an alkylthio group having 1 to 18 carbon atoms.

Examples of the halogen atom which is a substituent include chlorine, bromine, iodine, and fluorine.

Examples of the halogenated alkyl group having 1 to 4 carbon atoms which is a substituent include a trifluoromethyl group.

Examples of the alkoxy group having 1 to 18 carbon atoms which is a substituent include methoxy, ethoxy, propoxy, butoxy, tert-butoxy, pentyloxy, hexyloxy, heptyloxy, octyloxy, nonyloxy, decyloxy, undecyloxy, dodecyloxy, tridecyloxy, tetradecyloxy, pentadecyloxy, hexadecyloxy, heptadecyloxy, and octadecyloxy.

Examples of the alkylthio group having 1 to 18 carbon atoms which is a substituent include methylthio, ethylthio, propylthio, isopropylthio, butylthio, sec-butylthio, tert-butylthio, isobutylthio, amylthio, isoamylthio, tert-amylthio, hexylthio, heptylthio, isoheptylthio, tert-heptylthio, octylthio, isooctylthio, tert-octylthio, 2-ethylhexylthio, nonylthio, decylthio, undecylthio, dodecylthio, tridecylthio, tetradecylthio, pentadecylthio, hexadecylthio, heptadecylthio, and octadecylthio.

Examples of the aliphatic hydrocarbon group having 1 to 18 carbon atoms that may be represented by R¹ include an alkenyl group, an alkyl group, an alkyl group in which a methylene group is substituted with an alicyclic hydrocarbon group, an alkyl group in which a proton of a methylene group is substituted with an alicyclic hydrocarbon group, and an alkyl group in which an alicyclic hydrocarbon exists at a terminal.

Examples of the alkenyl group include allyl and 2-methyl-2-propenyl.

Examples of the alkyl group include methyl, ethyl, propyl, isopropyl, butyl, sec-butyl, tert-butyl, isobutyl, amyl, isoamyl, tert-amyl, hexyl, 2-hexyl, 3-hexyl, heptyl, 2-heptyl, 3-heptyl, isoheptyl, tert-heptyl, octyl, isooctyl, tert-octyl, 2-ethylhexyl, nonyl, isononyl, decyl, dodecyl, tridecyl, tetradecyl, pentadecyl, hexadecyl, heptadecyl, and octadecyl.

Examples of the alicyclic hydrocarbon group include, stating them in terms of the names of cycloalkanes constituting the respective alicyclic hydrocarbon groups: cyclopropane, cyclobutane, cyclopentane, cyclohexane, cycloheptane, cyclooctane, cyclodecane, bicyclo[2.1.1]hexane, bicyclo[2.2.1]heptane, bicyclo[3.2.1]octane, bicyclo[2.2.2]octane, and adamantane.

Examples of the aliphatic hydrocarbon group having 1 to 18 carbon atoms that is substituted with a halogen atom and may be represented by R¹ include halogenated alkyl groups, such as trifluoromethyl, pentafluoroethyl, 2-chloroethyl, 2-bromoethyl, heptafluoropropyl, 3-bromopropyl, nonafluorobutyl, tridecafluorohexyl, heptadecafluorooctyl, 2,2,2-trifluoroethyl, 1,1-difluoroethyl, 1,1-difluoropropyl, 1,1,2,2-tetrafluoropropyl, 3,3,3-trifluoropropyl, 2,2,3,3,3-pentafluoropropyl, norbornyl-1,1-difluoroethyl, norbornyltetrafluoroethyl, adamantane-1,1,2,2-tetrafluoropropyl, and bicyclo[2.2.1]heptane-tetrafluoromethyl.

Examples of the aliphatic hydrocarbon group having 1 to 18 carbon atoms that is substituted with an alkoxy group having 1 to 18 carbon atoms and may be represented by R¹ include a methoxymethyl group, a methoxyethyl group, a methoxypropyl group, a methoxybutyl group, a butoxymethyl group, an ethoxyethyl group, an ethoxypropyl group, and a propoxybutyl group.

Examples of the aliphatic hydrocarbon group having 1 to 18 carbon atoms that is substituted with an alkylthio group having 1 to 18 carbon atoms and may be represented by R¹ include 2-methylthioethyl, 4-methylthiobutyl and 4-butylthioethyl, and examples of the aliphatic hydrocarbon having 1 to 18 carbon atoms that is substituted with both a halogen atom and an alkylthio group having 1 to 18 carbon atoms include 1,1,2,2-tetrafluoro-3-methylthiopropyl.

Examples of the aryl group having 6 to 20 carbon atoms that may be represented by R¹ include phenyl, naphthyl, 2-methylphenyl, 3-methylphenyl, 4-methylphenyl, 4-vinylphenyl, 3-isopropylphenyl, 4-isopropylphenyl, 4-butylphenyl, 4-isobutylphenyl, 4-tert-butylphenyl, 4-hexylphenyl, 4-cyclohexylphenyl, 4-octylphenyl, 4-(2-ethylhexyl)phenyl, 2,3-dimethylphenyl, 2,4-dimethylphenyl, 2,5-dimethylphenyl, 2,6-dimethylphenyl, 3,4-dimethylphenyl, 3,5-dimethylphenyl, 2,4-di-tert-butylphenyl, 2,5-di-tert-butylphenyl, 2,6-di-tert-butylphenyl, 2,4-di-tert-pentylphenyl, 2,5-di-tert-amylphenyl, 2,5-di-tert-octylphenyl, cyclohexylphenyl, biphenyl, 2,4,5-trimethylphenyl, 2,4,6-trimethylphenyl, and 2,4,6-triisopropylphenyl.

Examples of the aryl group having 6 to 20 carbon atoms that is substituted with a halogen atom and may be represented by R¹ include pentafluorophenyl, chlorophenyl, dichlorophenyl, trichlorophenyl, 2,4-bis(trifluoromethyl)phenyl, and bromoethylphenyl.

Examples of the aryl group having 6 to 20 carbon atoms that is substituted with an alkoxy group having 1 to 18 carbon atoms and may be represented by R¹ include 2-methoxyphenyl and 2,4-dimethoxyphenyl.

Examples of the aryl group having 6 to 20 carbon atoms that is substituted with an alkylthio group having 1 to 18 carbon atoms and may be represented by R¹ include 4-methylthiophenyl, 4-butylthiophenyl, 4-octylthiophenyl, and 4-dodecylthiophenyl. Examples of the aryl group having 6 to 20 carbon atoms that is substituted with both a halogen atom and an alkylthio group having 1 to 18 carbon atoms include 1,2,5,6-tetrafluoro-4-methylthiophenyl, 1,2,5,6-tetrafluoro-4-butylthiophenyl, and 1,2,5,6-tetrafluoro-4-dodecylthiophenyl.

Examples of the arylalkyl group having 7 to 20 carbon atoms that may be represented by R¹ include benzyl, phenethyl, 2-phenylpropan-2-yl, diphenylmethyl, triphenylmethyl, styryl, and cinnamyl.

Examples of the arylalkyl group having 7 to 20 carbon atoms that is substituted with a halogen atom and may be represented by R¹ include pentafluorophenylmethyl, phenyldifluoromethyl, 2-phenyl-tetrafluoroethyl, and 2-(pentafluorophenyl)ethyl.

Examples of the arylalkyl group having 7 to 20 carbon atoms that is substituted with an alkoxy group having 1 to 18 carbon atoms and may be represented by R¹ include methoxybenzyl, dimethoxybenzyl, and ethoxybenzyl.

Examples of the arylalkyl group having 7 to 20 carbon atoms that is substituted with an alkylthio group having 1 to 18 carbon atoms and may be represented by R¹ include p-methylthiobenzyl. Examples of the arylalkyl group that is substituted with both a halogen atom and an alkylthio group having 1 to 18 carbon atoms include 2,3,5,6-tetrafluoro-4-methylthiophenylethyl.

The number of carbon atoms of the acyl group-substituted aryl group having 7 to 20 carbon atoms that may be represented by R¹ includes the carbon atoms of the acyl group.

Examples of such an aryl group include acetylphenyl, acetylnaphthyl, benzoylphenyl, 1-anthraquinolyl, and 2-anthraquinolyl.

Examples of the alicyclic hydrocarbon group having 3 to 12 carbon atoms that may be represented by R¹ include, stating them in terms of the names of cycloalkanes constituting the respective alicyclic hydrocarbon groups: cyclopropane, cyclobutane, cyclopentane, cyclohexane, cycloheptane, cyclooctane, cyclodecane, bicyclo[2.1.1]hexane, bicyclo[2.2.1]heptane, bicyclo[3.2.1]octane, bicyclo[2.2.2]octane, and adamantane.

Formula (II) is a group having at least one ether bond. In Formula (II), examples of the alkanediyl group having 1 to 4 carbon atoms that may be represented by Y¹ include methylene, ethylene, propane-1,3-diyl, propane-1,2-diyl, butylene, butane-1,3-diyl, butane-2,3-diyl, and butane-1,2-diyl.

Examples of the alkanediyl group having 2 to 6 carbon atoms that may be represented by R² and R³ include ethylene, propane-1,3-diyl, propane-1,2-diyl, butylene, butane-1,3-diyl, butane-2,3-diyl, butane-1,2-diyl, pentane-1,5-diyl, pentane-1,3-diyl, pentane-1,4-diyl, pentane-2,3-diyl, hexane-1,6-diyl, hexane-1,2-diyl, hexane-1,3-diyl, hexane-1,4-diyl, hexane-2,5-diyl, hexane-2,4-diyl, and hexane-3,4-diyl.

The halogenated alkanediyl group having 1 to 6 carbon atoms that may be represented by R² and R³ is any one of the above-described alkanediyl groups having 2 to 6 carbon atoms in which at least one proton is substituted with a halogen atom. Examples of the halogen atom include chlorine, bromine, iodine, and fluorine. Examples of the halogenated alkanediyl group having 1 to 6 carbon atoms include tetrafluoroethylene, 1,1-difluoroethylene, 1-fluoroethylene, 1,2-difluoroethylene, hexafluoropropane-1,3-diyl, 1,1,2,2-tetrafluoropropane-1,3-diyl, and 1,1,2,2-tetrafluoropentane-1,5-diyl.

Examples of the arylene group having 6 to 20 carbon atoms that may be represented by R² and R³ include 1,2-phenylene, 1,3-phenylene, 1,4-phenylene, 2,5-dimethyl-1,4-phenylene, 4,4′-biphenylene, diphenylmethane-4,4′-diyl, 2,2-diphenylpropane-4,4′-diyl, naphthalene-1,2-diyl, naphthalene-1,3-diyl, naphthalene-1,4-diyl, naphthalene-1,5-diyl, naphthalene-1,6-diyl, naphthalene-1,7-diyl, naphthalene-1,8-diyl, naphthalene-2,3-diyl, naphthalene-2,6-diyl, and naphthalene-2,7-diyl.

The halogenated arylene group having 6 to 20 carbon atoms that may be represented by R² and R³ is any one of the above-described arylene groups having 6 to 20 carbon atoms in which at least one proton is substituted with a halogen atom. Examples of the halogen atom include chlorine, bromine, iodine, and fluorine. Examples of the halogenated arylene group having 6 to 20 carbon atoms include tetrafluorophenylene.

Examples of the alkyl group having 1 to 18 carbon atoms that may be represented by R⁴ include methyl, ethyl, propyl, isopropyl, butyl, sec-butyl, tert-butyl, isobutyl, amyl, isoamyl, tert-amyl, hexyl, 2-hexyl, 3-hexyl, heptyl, 2-heptyl, 3-heptyl, isoheptyl, tert-heptyl, octyl, isooctyl, tert-octyl, 2-ethylhexyl, nonyl, isononyl, decyl, dodecyl, tridecyl, tetradecyl, pentadecyl, hexadecyl, heptadecyl, and octadecyl.

The halogenated alkyl group having 1 to 18 carbon atoms that may be represented by R⁴ is any one of the above-described alkyl groups having 1 to 18 carbon atoms in which at least one proton is substituted with a halogen atom. Examples of the halogen atom include chlorine, bromine, iodine, and fluorine. Examples of the halogenated alkyl group having 1 to 18 carbon atoms include halogenated alkyl groups, such as trifluoromethyl, pentafluoroethyl, heptafluoropropyl, nonafluorobutyl, tridecafluorohexyl, heptadecafluorooctyl, 2,2,2-trifluoroethyl, 1,1-difluoroethyl, 1,1-difluoropropyl, 1,1,2,2-tetrafluoropropyl, 3,3,3-trifluoropropyl, 2,2,3,3,3-pentafluoropropyl, and 1,1,2,2-tetrafluorotetradecyl.

Examples of the alicyclic hydrocarbon group having 3 to 12 carbon atoms that may be represented by R⁴ include, stating them in terms of the names of cycloalkanes constituting the respective alicyclic hydrocarbon groups: cyclopropane, cyclobutane, cyclopentane, cyclohexane, cycloheptane, cyclooctane, cyclodecane, bicyclo[2.1.1]hexane, bicyclo[2.2.1]heptane, bicyclo[3.2.1]octane, bicyclo[2.2.2]octane, and adamantane.

Examples of the aryl group having 6 to 20 carbon atoms, halogenated aryl group having 6 to 20 carbon atoms, arylalkyl group having 7 to 20 carbon atoms or halogenated arylalkyl group having 7 to 20 carbon atoms that may be represented by R⁴ include the same groups as those exemplified above for R¹.

A group preferred as Formula (II) is a group having a total of 2 to 18 carbon atoms in which fluorine is bound to a carbon atom of a group represented by R² that is adjacent to a sulfur atom since such a group has good acid generation capacity, cationic polymerizability and the like. Specific examples of the sulfonic acid derivative compound (A) used in the present invention include the following Compound Nos. 1 to 47.

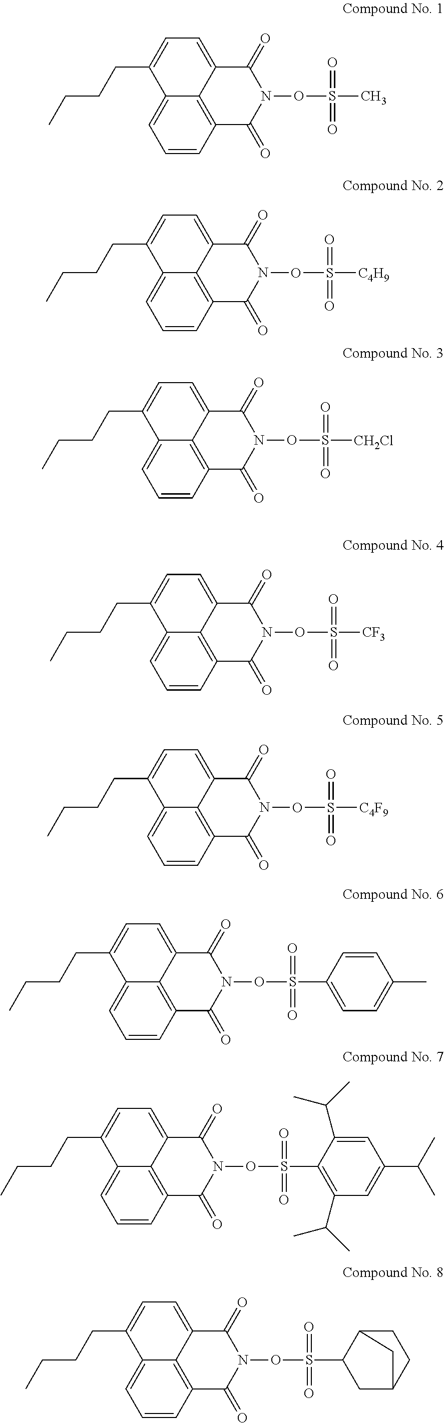

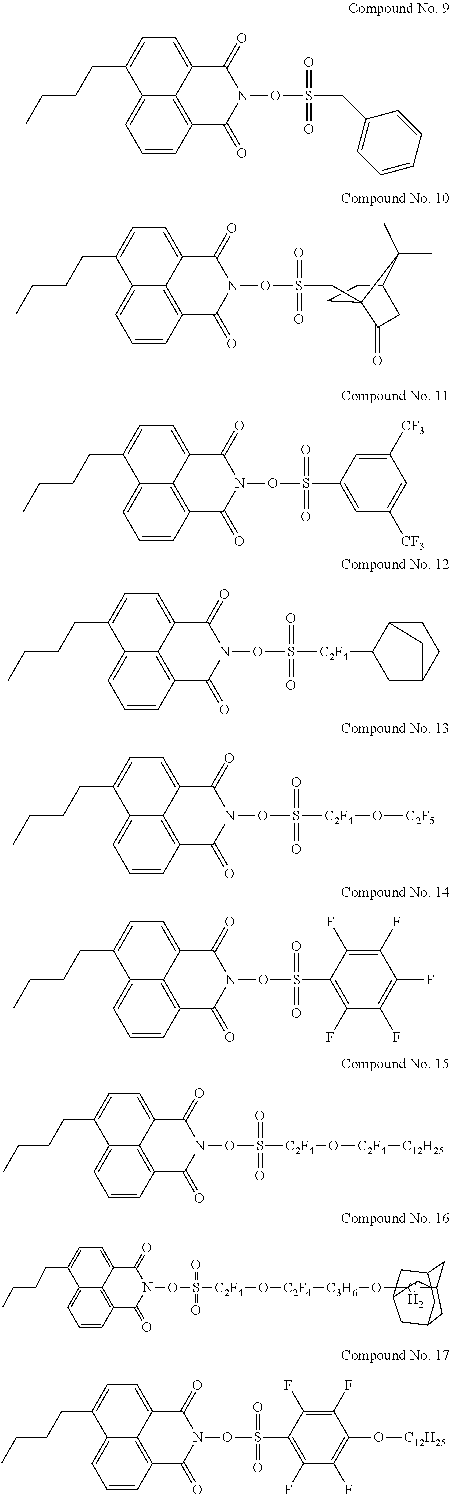

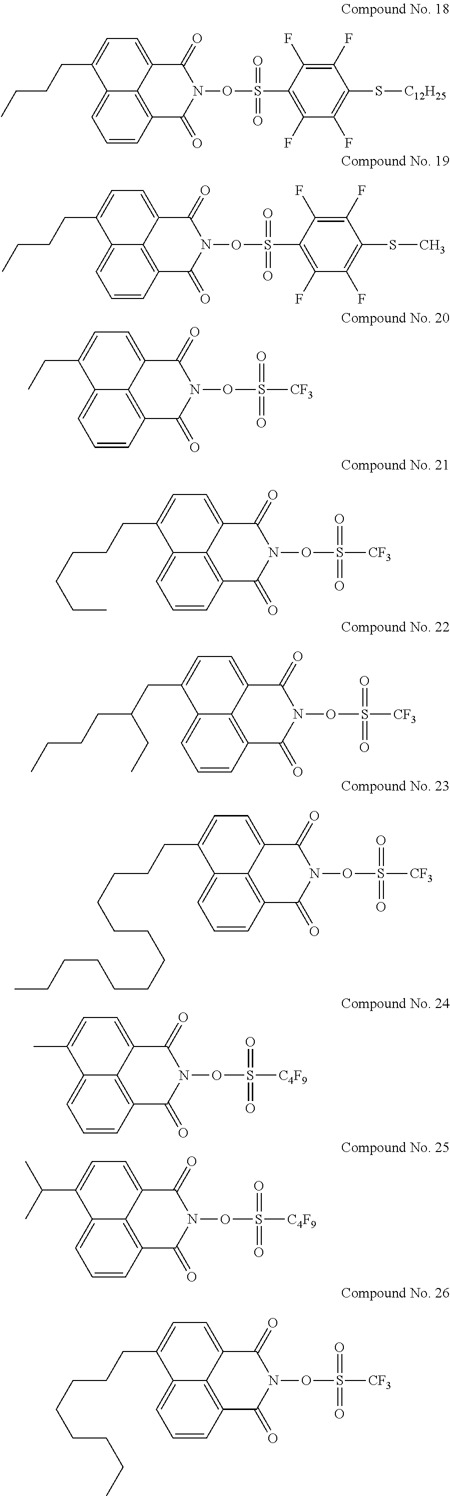

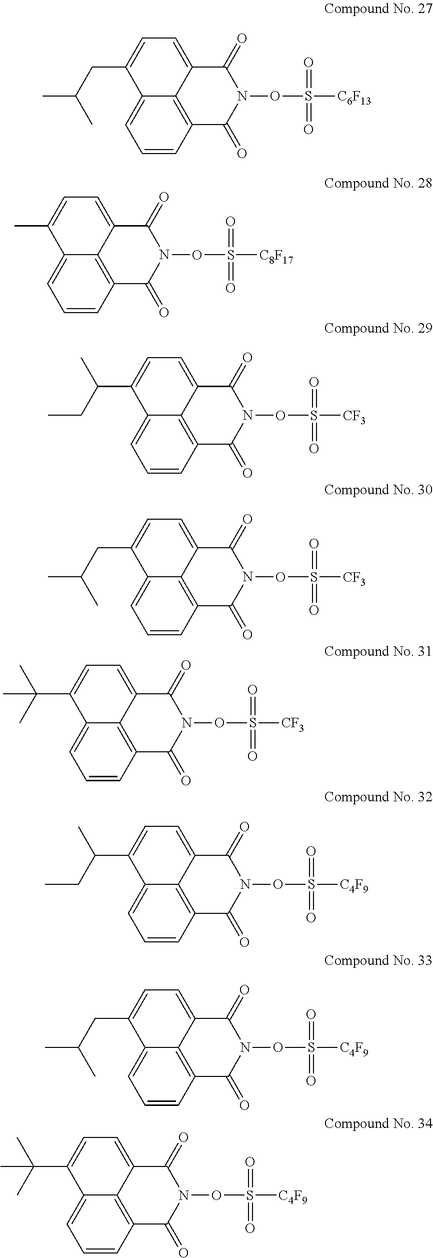

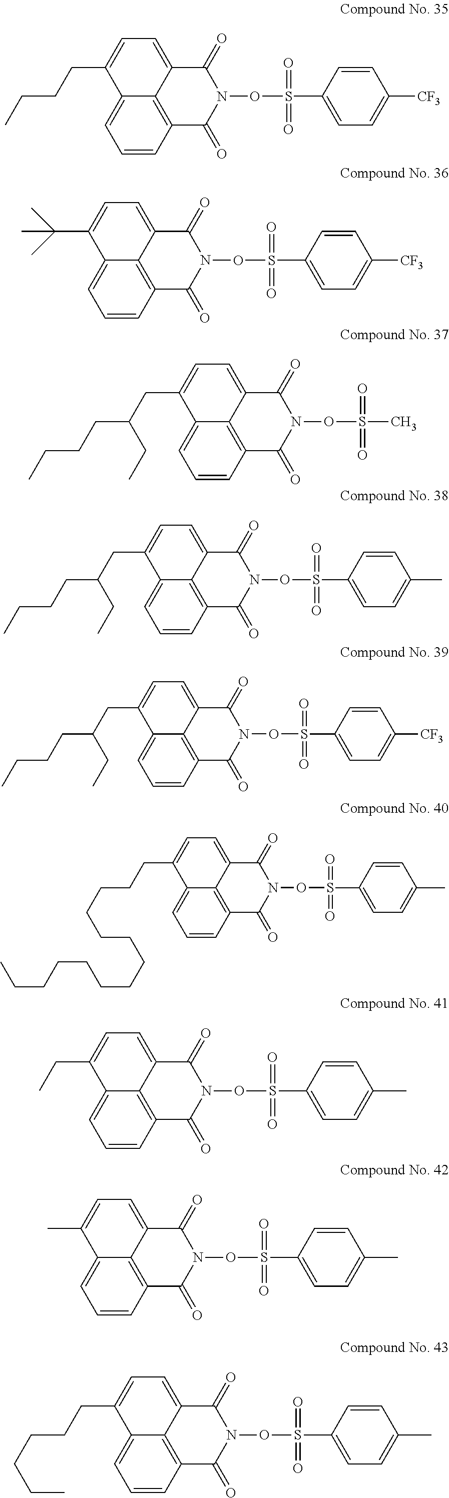

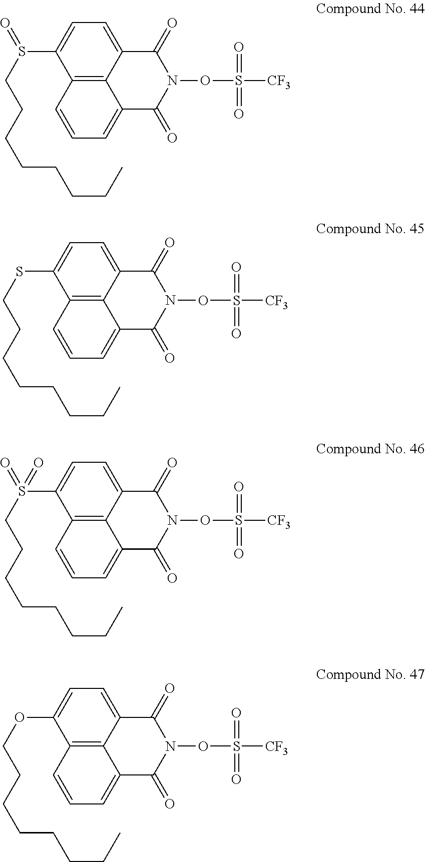

In Formula (I), R¹ may be selected such that the sulfonic acid derivative compound (A) releases an organic sulfonic acid appropriate for the intended use; however, R¹ is preferably a perfluoroalkyl group having 1 to 8 carbon atoms since a high acid strength is attained, and R¹ is more preferably a trifluoromethyl group, a pentafluoroethyl group, a heptafluoropropyl group, or a nonafluorobutyl group.

A method of producing the sulfonic acid derivative compound (A) represented by Formula (I) is not particularly restricted, and a well-known chemical reaction can be applied to synthesize the sulfonic acid derivative compound (A). For example, a method of synthesizing a sulfonic acid derivative compound using a bromide as a starting substance in the below-described manner can be employed.

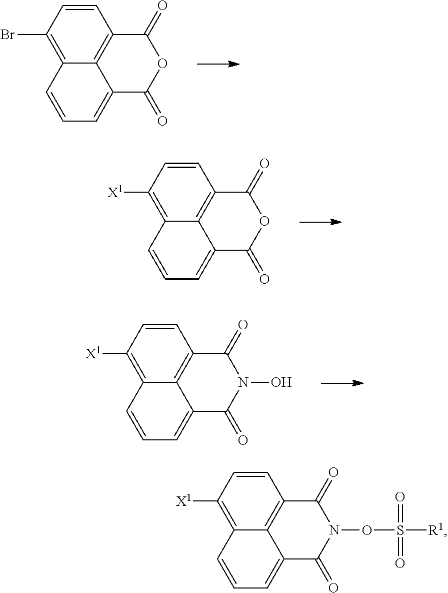

where X¹ and R¹ each represent the same group as in the above-described Formula (I).

### <Polymer Compound (B)>

In Formula (III), examples of the alkyl group having 1 to 4 carbon atoms and alkoxy group having 1 to 4 carbon atoms that may be represented by R⁶ include the same groups as those described above for R¹ in Formula (I), and examples of the alkoxycarbonyl group having 2 to 4 carbon atoms include acetyloxy, propionyloxy, and butanoyloxy.

The polymer compound (B) used in the present invention may be a homopolymer composed of one selected from structural units represented by Formula (III), a copolymer composed of two or more selected from structural units represented by Formula (III), or a copolymer containing a structural unit that does not correspond to Formula (III).

The homopolymer composed of one selected from structural units represented by Formula (III) or the copolymer composed of two or more selected from structural units represented by Formula (III) can be obtained by homopolymerizing or copolymerizing hydroxystyrene or a derivative thereof.

The copolymer containing a structural unit that does not correspond to Formula (III) can be obtained by copolymerizing one or more selected from hydroxystyrene and derivatives thereof with the below-described ethylenically unsaturated monomer.

Examples of the ethylenically unsaturated monomer include unsaturated aliphatic hydrocarbons, such as ethylene, propylene, butylene, isobutylene, cycloolefin, vinyl chloride, vinylidene chloride, vinylidene fluoride, tetrafluoroethylene, vinylnorbornene, vinyltrimethylsilane, and vinyltrimethoxysilane; mono(meth)acrylates of a polymer having a carboxyl group and a hydroxyl group at both terminals, such as (meth)acrylic acid, α-chloroacrylic acid, itaconic acid, maleic acid, citraconic acid, fumaric acid, himic acid, crotonic acid, isocrotonic acid, vinylacetic acid, allylacetic acid, cinnamic acid, sorbic acid, mesaconic acid, mono[2-(meth)acryloyloxyethyl]succinate, mono[2-(meth)acryloyloxyethyl]phthalate, and ω-carboxypolycaprolactone mono(meth)acrylate; unsaturated polybasic acids, such as hydroxyethyl (meth)acrylate-malate, hydroxypropyl (meth)acrylate-malate, dicyclopentadiene-malate, and polyfunctional (meth)acrylates having one carboxyl group and two or more (meth)acryloyl groups; esters formed between an unsaturated monobasic acid and a polyhydric alcohol or a polyhydric phenol, such as 2-hydroxyethyl (meth)acrylate, 2-hydroxypropyl (meth)acrylate, glycidyl (meth)acrylate, the below-described Compound Nos. A1 to A4, methyl (meth)acrylate, butyl (meth)acrylate, isobutyl (meth)acrylate, t-butyl (meth)acrylate, cyclohexyl (meth)acrylate, n-octyl (meth)acrylate, isooctyl (meth)acrylate, isononyl (meth)acrylate, stearyl (meth)acrylate, lauryl (meth)acrylate, methoxyethyl (meth)acrylate, dimethylaminomethyl (meth)acrylate, dimethylaminoethyl (meth)acrylate, aminopropyl (meth)acrylate, dimethylaminopropyl (meth)acrylate, ethoxyethyl (meth)acrylate, poly(ethoxy)ethyl (meth)acrylate, butoxyethoxyethyl (meth)acrylate, ethylhexyl (meth)acrylate, phenoxyethyl (meth)acrylate, tetrahydrofuryl (meth)acrylate, vinyl (meth)acrylate, allyl (meth)acrylate, benzyl (meth)acrylate, ethylene glycol di(meth)acrylate, diethylene glycol di(meth)acrylate, triethylene glycol di(meth)acrylate, polyethylene glycol di(meth)acrylate, propylene glycol di(meth)acrylate, 1,4-butanediol di(meth)acrylate, 1,6-hexanediol di(meth)acrylate, trimethylolethane tri(meth)acrylate, trimethylolpropane tri(meth)acrylate, dipentaerythritol hexa(meth)acrylate, dipentaerythritol penta(meth)acrylate, pentaerythritol tetra(meth)acrylate, pentaerythritol tri(meth)acrylate, tricyclodecane dimethylol di(meth)acrylate, tri[(meth)acryloylethyl]isocyanurate, and polyester (meth)acrylate oligomers; metal salts of unsaturated polybasic acids, such as zinc (meth)acrylate and magnesium (meth)acrylate; unsaturated polybasic acid anhydrides, such as maleic anhydride, itaconic anhydride, citraconic anhydride, methyltetrahydrophthalic anhydride, tetrahydrophthalic anhydride, trialkyltetrahydrophthalic anhydrides, 5-(2,5-dioxotetrahydrofuryl)-3-methyl-3-cyclohexene-1,2-dicarboxylic acid anhydride, trialkyltetrahydrophthalic anhydride-maleic anhydride adducts, dodecenylsuccinic anhydride, and methylhimic anhydride; amides formed by an unsaturated monobasic acid and a polyfunctional amine, such as (meth)acrylamide, methylene-bis(meth)acrylamide, diethylenetriamine-tris(meth)acrylamide, xylylene-bis(meth)acrylamide, α-chloroacrylamide, and N-2-hydroxyethyl (meth)acrylamide; unsaturated aldehydes, such as acrolein; unsaturated nitriles, such as (meth)acrylonitrile, α-chloroacrylonitrile, vinylidene cyanide, and allyl cyanide; unsaturated aromatic compounds, such as styrene, 4-methylstyrene, 4-ethylstyrene, 4-methoxystyrene, 4-hydroxystyrene, 4-chlorostyrene, 4-acetoxystyrene, ethoxy, 1-ethoxystyrene, divinylbenzene, vinyltoluene, vinylbenzoic acid, vinylphenol, vinylsulfonic acid, 4-vinylbenzenesulfonic acid, vinylbenzyl methyl ether, vinylbenzyl glycidyl ether, vinylbenzyl chloride, 2-vinylnaphthalene, vinylanthracene, vinylaniline, vinylbenzoate, isopropenyl phenol, and propenyl phenol; unsaturated heterocyclic compounds, such as N-vinylpyrrolidone, 1-vinylimidazole, 2-vinylpyridine, N-vinyllactam, 9-vinylcarbazole, maleimide, N-phenylmaleimide, and N-cyclohexylmaleimide; unsaturated ketones, such as methyl vinyl ketone; unsaturated amine compounds, such as vinylamine, allylamine, N-vinylpyrrolidone, and vinylpiperidine; vinyl alcohols, such as allyl alcohol and crotyl alcohol; vinyl ethers, such as vinylmethyl ether, vinylethyl ether, n-butylvinyl ether, isobutylvinyl ether, and allyl glycidyl ether; indenes, such as indene and 1-methylindene; aliphatic conjugated dienes, such as 1,3-butadiene, isoprene, and chloroprene; macromonomers having a mono(meth)acryloyl group at a terminal of a polymeric molecular chain, such as polystyrene, polymethyl (meth)acrylate, poly-n-butyl (meth)acrylate, and polysiloxanes; vinyl chloride; vinylidene chloride; divinyl succinate; diallyl phthalate; triallyl phosphate; triallyl isocyanurate; vinyl thioether; vinylimidazole; vinyloxazoline; vinylcarbazole; vinylpyrrolidone; vinylpyridine; vinylurethane compounds formed by a hydroxy group-containing vinyl monomer and a polyisocyanate compound; vinylepoxy compounds formed by a hydroxy group-containing vinyl monomer and a polyepoxy compound; and epoxy acrylate compounds.

Thereamong, mono(meth)acrylates of a polymer having a carboxyl group and a hydroxyl group at both terminals, polyfunctional (meth)acrylates having one carboxyl group and two or more (meth)acryloyl groups, and esters formed between an unsaturated monobasic acid and a polyhydric alcohol or a polyhydric phenol are preferred.

These polymerizable compounds may be used individually or in combination of two or more thereof and, when two or more polymerizable compounds are used in combination, they may be copolymerized in advance to be used as a copolymer.

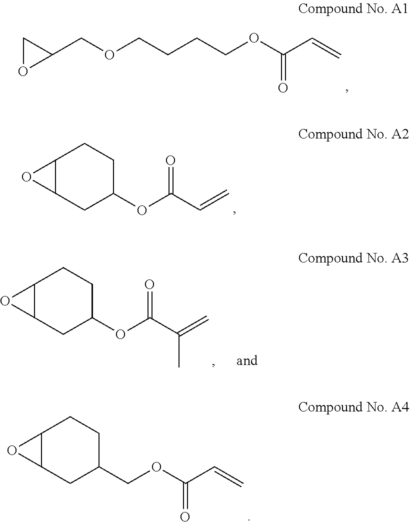

In the polymer compound (B), from the standpoint of improving the moist-heat resistance, the content of the structural unit represented by Formula (III) is 20 to 100% by mole, preferably 50 to 90% by mole.

In the polymer compound (B), the hydroxy groups or carboxyl groups that impart alkali solubility to a resin may be protected with a protecting group that can be cleaved by the action of an acid, whereby alkali insolubility or poor alkali solubility can be imparted. Examples of the protecting group include tertiary alkyl groups, saturated alicyclic hydrocarbon groups such as adamantly, trialkylsilyl groups, oxoalkyl groups, aryl group-substituted alkyl groups, heteroalicyclic groups such as an anthracenyl-tetrahydropyran-2-yl group, tertiary alkylcarbonyl groups, tertiary alkylcarbonylalkyl groups, tertiary alkyloxycarbonyl groups, tertiary alkyloxycarbonylalkyl groups, alkoxyalkyl groups, thioalkoxyalkyl groups, and acetal groups such as a tetrahydropyranyl group, a tetrahydrofuranyl group and a thiofuranyl group.

In the polymer compound (B), from the standpoint of solubility, it is preferred that the protecting group be introduced to 10 to 60% by mole of the hydroxy groups or carboxyl groups.

In the polymer compound (B), examples of the structural unit that does not correspond to Formula (III) include the followings:

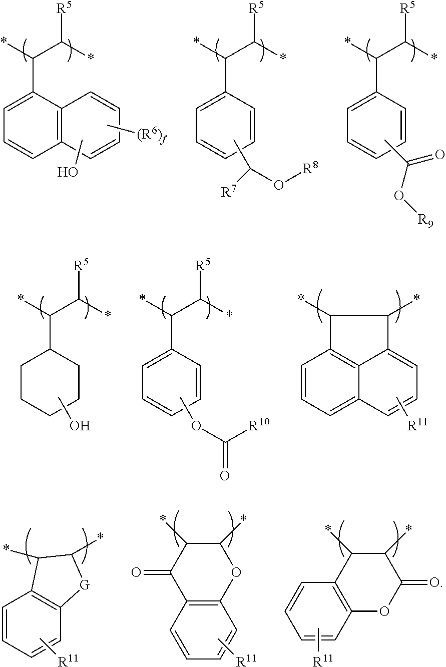

In the above-described formulae, R⁷ represents an alkyl group having 1 to 4 carbon atoms and R⁸ represents an alkyl group having 1 to 6 carbon atoms or a cycloalkyl group having 5 to 7 carbon atoms, or R⁷ and R⁸ are bound with each other to form a trimethylene chain or a tetramethylene chain; R⁹ represents a hydrocarbon group having 1 to 20 carbon atoms; R¹⁰ represents a hydrocarbon group having 1 to 10 carbon atoms; R¹ represents a hydrogen atom, an unsubstituted or halogen atom-substituted alkyl group having 1 to 20 carbon atoms, a hydroxy group, an alkoxy group having 1 to 20 carbon atoms, an alkanoyl group having 2 to 20 carbon atoms, an alkoxycarbonyl group having 2 to 20 carbon atoms, an aryl group having 6 to 10 carbon atoms, or a halogen atom; G represents methylene, an oxygen atom, or a sulfur atom; and R⁵, R⁶ and f have the same meanings as in Formula (III).

The polystyrene-equivalent weight-average molecular weight (Mw) of the polymer compound (B), which is determined by gel permeation chromatography (GPC), is usually 1,000 to 500,000, preferably 2,000 to 200,000, more preferably 3,000 to 100,000. In this case, when the Mw of the polymer compound (B) is less than 1,000, the heat resistance of a cured product of the positive photosensitive composition tends to be reduced, whereas when the Mw is higher than 500,000, the developability and the coatability of a cured product of the positive photosensitive composition tend to be deteriorated.

In the positive photosensitive composition of the present invention, the sulfonic acid derivative compound (A) represented by Formula (I) is used at a ratio of preferably 0.01 to 20 parts by mass, more preferably 0.5 to 10 parts by mass, with respect to 100 parts by mass of a component(s) other than a solvent of the polymer compound (B). When the sulfonic acid derivative compound (A) is used in an amount of less than 0.01 parts by mass, the sensitivity and the developability may be deteriorated, whereas when this amount is greater than 20 parts by mass, the transparency to radiation is reduced, which can make it difficult to obtain a rectangular resist pattern.

The positive photosensitive composition of the present invention is particularly useful as a chemically amplified resist. By the action of an acid generated from a photoacid generator containing the sulfonic acid derivative compound (A) represented by Formula (I) upon exposure, the positive photosensitive composition of the present invention is made soluble in a developing solution through a polarity change induced by a deprotection reaction of a side chain of the polymer compound, such as cleavage of a chemical bond of an ester group, an acetal group or the like.

### <Optional Component (C)>

In the positive photosensitive composition of the present invention, a photoacid generator other than the sulfonic acid derivative compound (A) used in the present invention may be used as an optional component (C).

Examples of such other photoacid generator include iodonium salt compounds and sulfonium compounds and, when such other photoacid generator is used in combination, the amount thereof is preferably 10 to 200 parts by mass with respect to 100 parts by mass of the sulfonic acid derivative compound (A) used in the present invention.

To the positive photosensitive composition of the present invention, a phenol resin, a phenol-novolac resin or a cresol-novolac resin may also be added.

To the positive photosensitive composition of the present invention, a quinoneazide compound may be further added.

In the positive photosensitive composition of the present invention, various additives may be incorporated as well. Examples of the various additives include various resin additives, such as a base quencher, an acid amplifier, a base generator, a dissolution inhibitor, an inorganic filler, an organic filler, a coloring agent (e.g., a pigment or a dye), an antifoaming agent, a thickening agent, a flame retardant, an antioxidant, a stabilizer, and a leveling agent. In the positive photosensitive composition of the present invention, these additives are used in a total amount of preferably 50% by mass or less.

In the positive photosensitive composition of the present invention, in order to facilitate dissolution of the sulfonic acid derivative compound (A) used in the present invention, the sulfonic acid derivative compound (A) can be dissolved in an appropriate solvent, such as propylene carbonate, carbitol, carbitol acetate, butyrolactone or propylene glycol-1-monomethylether-2-acetate, in advance prior to its use.

The positive photosensitive composition of the present invention is, prior to its use, normally adjusted by being dissolved in a solvent such that a total amount of the components (A), (B) and (C) is usually 5 to 50% by mass, preferably 10 to 25% by mass, with respect to the total amount of the composition, and subsequently filtered through, for example, a filter having a pore size of about 0.2 μm. The positive photosensitive composition of the present invention can be prepared by a method of, for example, mixing, dissolving or kneading the components (A) and (B) along with other optional component(s) (C).

A pattern can be formed by irradiating the positive photosensitive composition of the present invention with heat or light. A light source used for exposure of the positive photosensitive composition is selected as appropriate from those emitting g-line (436 nm), h-line (405 nm), i-line (365 nm), DUV (248 nm), visible light, ultraviolet radiation, far-ultraviolet radiation, X-ray, charged particle beam, electron beam, ion beam or the like in accordance with the type of the photoacid generator to be used.

The positive photosensitive composition of the present invention is coated on a substrate made of silicon or the like by an appropriate coating method using a spinner, a coater or the like, subsequently exposed through a prescribed mask, post-baked for improvement of the apparent sensitivity of the resulting resist and then developed, whereby a more favorable resist pattern can be obtained.

Specific examples of the applications of the positive photosensitive composition of the present invention include, but not particularly limited to: optical filters; paints; coating agents; lining agents; adhesives; printing plates; insulating varnishes; insulation sheets; laminated plates; printed circuit boards; sealants for semiconductor devices, LED packages, liquid crystal inlets, organic EL devices, optical elements, electrical insulating materials, electronic components, separation membranes and the like; molded materials; putties; glass fiber impregnants; fillers; passivation films for semiconductors, solar cells and the like; interlayer insulation films and surface protection films that are used in thin-film transistors (TFT), liquid crystal displays, organic EL displays, printed boards and the like; color filters of printed boards, color televisions, PC monitors, personal digital assistants and CCD image sensors; electrode materials for plasma display panels; printing inks; dental compositions; resins for stereolithography; liquid-form films and dry films; micromachine components; glass fiber cable coatings; materials for holographic recording; magnetic recording materials; optical switches; plating masks; etching masks; screen printing stencils; touch panels such as transparent conductive films; MEMS elements; nanoimprint materials; photofabrication applications, such as two-dimensional and three-dimensional high-density mounting and the like of semiconductor packages; decoration sheets; artificial nails; glass-alternative optical films; electronic papers; optical disks; micro-lens arrays used in projectors, optical communication lasers and the like; prism lens sheets used in backlights of liquid crystal displays; Fresnel lens sheets used in the screens of projection televisions and the like; lens parts of lens sheets such as lenticular lens sheets; backlights and the like using such sheets; optical lenses, such as microlenses and image pickup lenses; optical elements; optical connectors; optical waveguides; insulation packings; heat-shrinkable rubber tubes; O-rings; sealing agents for display devices; protective materials; optical fiber protection materials; adhesives; die bonding agents; high heat radiation materials; high-heat-resistant sealing materials; members for solar cells, fuel cells and secondary batteries; solid electrolytes for batteries; insulation coating materials; heat-sensitive drums for copying machines; gas separation membranes; civil engineering and construction materials, such as concrete protecting materials, linings, soil injection agents, sealing agents, cold-heat storage materials, glass coatings and foams; medical materials, such as tube/seal materials, coating materials, sealing materials for sterilizers, contact lenses, oxygen enrichment membranes, and biochips; automobile components; and various mechanical components.

### EXAMPLES

The present invention will now be described in more detail by way of Examples and Comparative Examples; however, the present invention is not restricted thereto.

### <Preparation of Positive Photosensitive Compositions and Production of Positive Resist Films>

Compositions were each prepared in accordance with the formulations shown in [Table 1] and [Table 2]. The thus obtained compositions were each filtered through a 1-μm microfilter and spin-coated (350 rpm, 7 seconds) on a glass substrate such that the resulting film would have a thickness of 30.0 μm after pre-baking. Subsequently, the resultants were pre-baked on a hot plate at 110° C. for 180 seconds, whereby positive resist films were obtained. It is noted here that the unit of the amounts shown in Tables below is parts by mass.

### Example 1 and Comparative Examples 1 to 5

The positive resist films obtained in Example 1 and Comparative Examples 1 to 5 were each exposed using a high-pressure mercury lamp and subsequently subjected to 120-second PEB (Post-Exposure Baking) at 120° C. and 60-second development in a 2.38% aqueous tetramethylammonium hydroxide solution. After the development, the film thickness was measured, and the exposure dose which resulted in a film thickness of 0 μm was defined as sensitivity exposure dose. An evaluation of ∘ was given when the sensitivity exposure dose was less than 40 mJ/cm², and an evaluation of x was given when the sensitivity exposure dose was 40 mJ/cm² or higher. The results thereof are shown in [Table 1].

### Example 2 and Comparative Examples 6 to 10

The positive resist films obtained in Example 2 and Comparative Examples 6 to 10 were each exposed using a high-pressure mercury lamp and subsequently developed for 60 seconds in a 2.38% aqueous tetramethylammonium hydroxide solution. After the development, the film thickness was measured, and the exposure dose which resulted in a film thickness of 0 μm was defined as sensitivity exposure dose. An evaluation of ∘ was given when the sensitivity exposure dose was less than 40 mJ/cm², and an evaluation of x was given when the sensitivity exposure dose was 40 mJ/cm² or higher. The results thereof are shown in [Table 2].

TABLE 1

| | | Example | Comparative | Comparative | Comparative | Comparative | Comparative |
|---|---|---|---|---|---|---|---|
| | | 1 | Example 1 | Example 2 | Example 3 | Example 4 | Example 5 |
| A | A-1 | 0.32 | 0.32 | — | — | — | — |
| | A′-1 | — | — | 0.32 | 0.32 | — | — |
| | A′-2 | — | — | — | — | 0.32 | 0.32 |
| B | B-1 | 90.34 | — | 90.34 | — | 90.34 | — |
| | B′-1 | — | 90.34 | — | 90.34 | — | 90.34 |
| C | C-1 | 6.32 | 6.32 | 6.32 | 6.32 | 6.32 | 6.32 |
| D | D-1 | 3.02 | 3.02 | 3.02 | 3.02 | 3.02 | 3.02 |

| | | | | | | |
|---|---|---|---|---|---|---|
| Sensitivity | ∘ | x | x | x | x | x |
| exposure | | | | | | |
| dose | | | | | | |

TABLE 2

| | | Example | Comparative | Comparative | Comparative | Comparative | Comparative |
|---|---|---|---|---|---|---|---|
| | | 2 | Example 6 | Example 7 | Example 8 | Example 9 | Example 10 |
| A | A-1 | 0.32 | 0.32 | — | — | — | — |
| | A′-1 | — | — | 0.32 | 0.32 | — | — |
| | A′-2 | — | — | — | — | 0.32 | 0.32 |
| B | B-2 | 90.34 | — | 90.34 | — | 90.34 | — |
| | B′-1 | — | 90.34 | — | 90.34 | — | 90.34 |
| C | C-1 | 6.32 | 6.32 | 6.32 | 6.32 | 6.32 | 6.32 |
| D | D-1 | 3.02 | 3.02 | 3.02 | 3.02 | 3.02 | 3.02 |

| | | | | | | |
|---|---|---|---|---|---|---|
| Sensitivity | ∘ | x | x | x | x | x |
| exposure | | | | | | |
| dose | | | | | | |

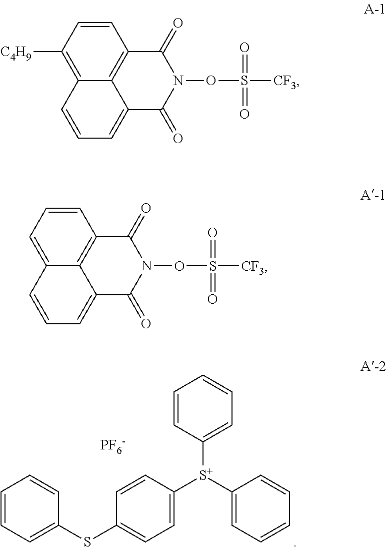

B-1: a 35% PGMEA solution of a resin (Mw=12,000) having a structure in which 30% by mole of poly(p-hydroxystyrene) is substituted with t-butoxycarbonyl groups.

B-2: a 35% PGMEA solution of a resin (Mw=12,000) having a structure in which 30% by mole of poly(p-hydroxystyrene) is substituted with acetal groups.

B′-1: SPC-1000 (manufactured by Showa Denko K.K.).

C-1: a 1% PGMEA solution of FZ-2122 (leveling agent, manufactured by Dow Corning Toray Co., Ltd.).

D-1: PGMEA.

From Tables 1 and 2 above, the positive resists containing the sulfonic acid derivative compound according to the present invention were confirmed to exhibit higher sensitivity at the time of being cured as compared to the positive resists containing a comparative compound.

1.-6. (canceled)

7. A positive photosensitive composition comprising:
a sulfonic acid derivative compound (A) represented by the following Formula (I): 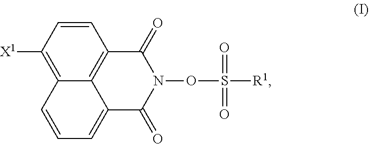
where X¹ represents a linear or branched alkyl group having 1 to 14 carbon atoms; a methylene group in the alkyl group is optionally substituted with —S—, —O—, —SO— or —SO₂—; R¹ represents an aliphatic hydrocarbon group having 1 to 18 carbon atoms, an aryl group having 6 to 20 carbon atoms, an arylalkyl group having 7 to 20 carbon atoms, an acyl group-substituted aryl group having 7 to 20 carbon atoms, an alicyclic hydrocarbon group having 3 to 12 carbon atoms, a 10-camphoryl group, or a group represented by the following Formula (II): 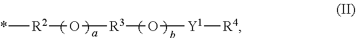
where Y¹ represents a single bond or an alkanediyl group having 1 to 4 carbon atoms; R² and R³ each independently represent an alkanediyl group having 2 to 6 carbon atoms, a halogenated alkanediyl group having 1 to 6 carbon atoms, an arylene group having 6 to 20 carbon atoms, or a halogenated arylene group having 6 to 20 carbon atoms; R⁴ represents a linear or branched alkyl group having 1 to 18 carbon atoms, a linear or branched halogenated alkyl group having 1 to 18 carbon atoms, an alicyclic hydrocarbon group having 3 to 12 carbon atoms, an aryl group having 6 to 20 carbon atoms, a halogenated aryl group having 6 to 20 carbon atoms, an arylalkyl group having 7 to 20 carbon atoms, or a halogenated arylalkyl group having 7 to 20 carbon atoms; a and b each represent 0 or 1; either a or b is 1; and a symbol “*” means that this group is bound with an adjacent group at the site “*”; and
the aliphatic hydrocarbon group having 1 to 18 carbon atoms, the aryl group having 6 to 20 carbon atoms, the arylalkyl group having 7 to 20 carbon atoms or the alicyclic hydrocarbon group having 3 to 12 carbon atoms has no substituent, or is optionally substituted with a halogen atom or a group selected from a halogenated alkyl group having 1 to 4 carbon atoms, an alkoxy group having 1 to 18 carbon atoms and an alkylthio group having 1 to 18 carbon atoms; and
a polymer compound (B) required to contain a structural unit represented by the following Formula (III): 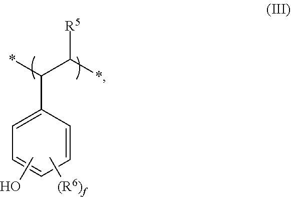
where R⁵ represents a hydrogen atom or a methyl group; R⁶ represents an alkyl group having 1 to 4 carbon atoms, an alkoxy group having 1 to 4 carbon atoms, or an alkoxycarbonyl group having 2 to 4 carbon atoms; f represents a number of 0 to 4; and symbols “*” mean that this group is bound with adjacent groups at the sites “*”.

8. The positive photosensitive composition according to claim 7, wherein X¹ is an alkyl group having 3 to 8 carbon atoms.

9. The positive photosensitive composition according to claim 7, wherein X¹ is an alkyl group having 4 carbon atoms.

10. The positive photosensitive composition according to claim 7, wherein R¹ is a perfluoroalkyl group having 1 to 8 carbon atoms.

11. The positive photosensitive composition according to claim 8, wherein R¹ is a perfluoroalkyl group having 1 to 8 carbon atoms.

12. The positive photosensitive composition according to claim 7, wherein, in the polymer compound (B), the ratio of the structural unit represented by the Formula (III) is 50 to 90% by mole.

13. The positive photosensitive composition according to claim 8, wherein, in the polymer compound (B), the ratio of the structural unit represented by the Formula (III) is 50 to 90% by mole.

14. The positive photosensitive composition according to claim 10, wherein, in the polymer compound (B), the ratio of the structural unit represented by the Formula (III) is 50 to 90% by mole.

15. A pattern obtained using the positive photosensitive composition according to claim 7.

16. The pattern according to claim 15, wherein X¹ is an alkyl group having 3 to 8 carbon atoms.

17. The pattern according to claim 15, wherein X¹ is an alkyl group having 4 carbon atoms.

18. The pattern according to claim 15, wherein R¹ is a perfluoroalkyl group having 1 to 8 carbon atoms.

19. The pattern according to claim 15, wherein, in the polymer compound (B), the ratio of the structural unit represented by the Formula (III) is 50 to 90% by mole.

20. A method of producing a pattern, the method comprising forming a pattern by irradiating the positive photosensitive composition according to claim 7 with heat or light.

21. The method of producing a pattern according to claim 20, wherein X¹ is an alkyl group having 3 to 8 carbon atoms.

22. The method of producing a pattern according to claim 20, wherein X¹ is an alkyl group having 4 carbon atoms.

23. The method of producing a pattern according to claim 20, wherein R¹ is a perfluoroalkyl group having 1 to 8 carbon atoms.

24. The method of producing a pattern according to claim 20, wherein, in the polymer compound (B), the ratio of the structural unit represented by the Formula (III) is 50 to 90% by mole.
